(19) United States
(12) Patent Application Publication
(10) Pub. No.: US 2026/0143991 A1
(43) Pub. Date: May 21, 2026

(54) SUBSTRATE PROCESSING APPARATUS

(71) Applicant: Samsung Electronics Co., Ltd., Suwon-si (KR)

(72) Inventors: Youngmin CHOI, Suwon-si (KR); Joonhoi KIM, Suwon-si (KR); Kyungsoon PARK, Suwon-si (KR); Namtae HEO, Suwon-si (KR)

(73) Assignee: Samsung Electronics Co., Ltd., Suwon-si (KR)

(21) Appl. No.: 19/328,668

(22) Filed: Sep. 15, 2025

(30) Foreign Application Priority Data
Nov. 19, 2024 (KR) 10-2024-0165337

(51) Int. Cl. H01L 21/67

(52) U.S. Cl. CPC H10P 72/0414

(57) ABSTRACT

A substrate processing apparatus includes a substrate stage including a seating surface for receiving the substrate, the substrate stage being arranged such that the substrate placed on the seating surface faces downward; a nozzle portion located below the substrate stage and for spraying a cleaning fluid toward the substrate; a chamber including a body portion and a curved portion connected to the body portion, the body portion having a cylindrical shape extending vertically downward to surround the substrate stage and the curved portion having a diameter that decreases as the curved portion extends vertically downward; an exhaust duct connected to the curved portion of the chamber, wherein the curved portion comprises a first curved portion extending vertically downward and having a convex curved surface facing outward and a second curved portion connected to the first curved portion and extending vertically downward to have a convex curved surface facing inward.

### CROSS-REFERENCE TO RELATED APPLICATION

This application claims priority from Korean Patent Application No. 10-2024-0165337, filed on November 19, 2024, in the Korean Intellectual Property Office (KIPO), and all the benefits accruing therefrom under 35 U.S.C. §119, the entire contents of which are herein incorporated by reference.

### TECHNICAL FIELD

Apparatuses and methods consistent with some embodiments of the present disclosure relate to a substrate processing apparatus, and more particularly, a substrate processing apparatus for processing a substrate using a cleaning fluid.

### BACKGROUND

In a semiconductor manufacturing process using a semiconductor wafer, it may be important to protect circuit patterns on the semiconductor wafers. The circuit patterns on the semiconductor wafer may be vulnerable to contamination, so a wafer cleaning process is desirable. However, during the wafer cleaning process, foreign substances may fly out and deposit on a semiconductor wafer, resulting in wafer surface contamination. In particular, when performing a laser grooving process that directly processes a scribe lane of the semiconductor wafer, a large amount of fine silicon molecules may be generated, which increases the problem of wafer contamination.

In some existing wafer cleaning methods, where a cleaning fluid is used, foreign substances may be re-dispersed onto the semiconductor wafer because the cleaning chamber may not be exhausted properly. Therefore, there is a need for a substrate processing apparatus capable of preventing re-dispersion of foreign substances, and effectively cleaning the wafer through more efficient exhaust performance.

### SUMMARY

At least some embodiments of the present disclosure provide a substrate processing apparatus capable of preventing re-dispersion of foreign substances during a substrate cleaning process using a cleaning fluid.

Some embodiments of the present disclosure provide a substrate processing apparatus including a substrate support comprising a substrate stage ,the substrate stage includes a seating surface configured to receive a substrate, the substrate stage being arranged such that the substrate placed on the seating surface faces downward. The apparatus includes a nozzle portion configured to spray a cleaning fluid toward the substrate, a chamber including a body portion and a curved portion connected to the body portion, the body portion having a cylindrical shape extending vertically downward to surround the substrate stage and the curved portion having a diameter that decreases as the curved portion extends vertically downward, and an exhaust duct connected to the curved portion of the chamber, wherein the curved portion includes a first curved portion extending vertically downward and having a convex curved surface facing outward and a second curved portion connected to the first curved portion and extending vertically downward and having a convex curved surface facing inward.

Some embodiments of the present disclosure provide a substrate processing apparatus including a substrate support comprising a substrate stage, the substrate stage includes a seating surface configured to receive a substrate, the substrate stage being arranged such that the substrate placed on the seating surface faces downward. The apparatus includes a nozzle portion located below the substrate stage and configured to spray a cleaning fluid toward the substrate, a chamber including a body portion surrounding the substrate support, a first curved portion connected to the body portion and extending vertically downward to have a convex curved surface facing outward, and a second curved portion connected to the first curved portion and extending vertically downward to have a convex curved surface facing inward, at least one exhaust hole disposed on a side surface of the body portion, an exhaust duct connected to the chamber, and a rotational airflow prevention portion extending vertically downward within an internal space enclosed by the first curved portion and the second curved portion and configured to partition the internal space.

Some embodiments of the present disclosure provide a substrate processing apparatus includes a substrate support comprising a substrate stage, the substrate stage includes a seating surface configured to receive a substrate, the substrate stage being arranged such that the substrate placed on the seating surface faces downward. The apparatus includes a nozzle portion located below the substrate stage and configured to spray a cleaning fluid toward the substrate, a cylindrical body portion extending vertically downward to surround the substrate stage, the cylindrical body portion extending to have a first height within a range of 1.2 times to 2.3 times a diameter of the substrate stage, a first curved portion connected to the body portion and extending vertically downward to have a convex curved surface facing outward, at least a portion of the first curved portion having a first radius of curvature from a first center point, a second curved portion connected to the first curved portion to share a common tangent at a point where a lower surface of the first curved portion and an upper surface of the second curved portion meets, the second curved portion extending vertically downward to have a convex curved surface facing inward, at least a portion of the second curved portion having a second radius of curvature from a second center point, a plurality of exhaust holes arranged between the substrate stage and the nozzle portion on a side surface of the cylindrical body portion, the plurality of exhaust holes arranged to surround the substrate support on the side surface of the cylindrical body portion, the plurality of exhaust holes being spaced apart from each other, an exhaust duct connected to the second curved portion and a rotational airflow prevention portion having a center rod extending vertically downward within an internal space enclosed by the first curved portion and the second curved portion, and a plurality of plates extending radially from the center rod and configured to divide the internal space, an outer surface of each of the plurality of plates extending along a profile of an inner circumferential surface of the first curved portion and an inner circumferential surface of the second curved portion.

In a substrate processing apparatus in accordance with some embodiments, a substrate may be placed on a substrate support such that a surface of the substrate to be cleaned faces downward, and a nozzle head of a nozzle portion may spray a cleaning fluid in a direction from a bottom to a top toward the surface of the substrate. Additionally, a plurality of exhaust holes may be arranged to surround a body of a chamber at a height at which the nozzle head for spraying the cleaning fluid is arranged, an exhaust duct may be arranged at a lower portion of the chamber, and a rotational air flow prevention portion may be arranged within the chamber.

Accordingly, the cleaning fluid and foreign substances may be primarily exhausted from the plurality of exhaust holes, flow to the lower surface of the chamber, and be exhausted to the exhaust duct without generating a rotational air flow by the rotational air flow prevention portion. Thus, compared to related arts in which the cleaning fluid is sprayed downward on the semiconductor substrate, it may be possible to effectively prevent the phenomenon in which foreign substances generated during cleaning are being re-dispersed onto the semiconductor substrate.

### BRIEF DESCRIPTION OF THE DRAWINGS

The accompanying drawings are included to provide a further understanding of disclosed example embodiments, and are incorporated in and constitute a part of this specification. In the drawings:

FIG. 1 illustrates a schematic of a substrate processing apparatus, consistent with some embodiments of the present disclosure.

FIG. 2 illustrates a partially cut-away perspective view of an exemplary substrate processing apparatus, consistent with some embodiments of the present disclosure.

FIG. 3 illustrates an enlarged cross-sectional view of portion ‘A’ shown in FIG. 1, consistent with some embodiments of the present disclosure.

FIG. 4 illustrates an enlarged cross-sectional view of portion ‘B’ shown in FIG. 1, consistent with some embodiments of the present disclosure.

FIG. 5 illustrates a cross-sectional view of an exemplary substrate processing apparatus taken along the line C-Cʹ in FIG. 1, consistent with some embodiments of the present disclosure.

FIG. 6 illustrates a cross-sectional view of an exemplary substrate processing apparatus taken along the line D-Dʹ in FIG. 1, consistent with some embodiments of the present disclosure.

FIG. 7 illustrates a cross-sectional view of an exemplary substrate processing apparatus taken along the line E-Eʹ in FIG. 6, consistent with some embodiments of the present disclosure.

FIGS. 8 to 10 illustrate data explaining results of a flow analysis conducted on an exemplary substrate processing apparatus, consistent with some embodiments of the present disclosure.

FIG. 11 illustrates a schematic of a substrate processing apparatus, consistent with some embodiments of the present disclosure.

FIG. 12 illustrates a cross-section view of an exemplary substrate processing apparatus taken along the line F-Fʹ in FIG. 11, consistent with some embodiments of the present disclosure.

FIG. 13 illustrates a schematic of a substrate processing apparatus, consistent with some embodiments of the present disclosure.

FIG. 14 illustrates a cross-section view of an exemplary substrate processing apparatus taken along the line G-Gʹ in FIG. 13, consistent with some embodiments of the present disclosure.

FIG. 15 illustrates a schematic of a substrate processing apparatus, consistent with some embodiments of the present disclosure.

FIG. 16 illustrates a cross-section view of an exemplary substrate processing apparatus taken along the line H-Hʹ in FIG. 15, consistent with some embodiments of the present disclosure.

FIG. 17 illustrates a schematic of a substrate processing apparatus, consistent with some embodiments of the present disclosure.

FIG. 18 illustrates a cross-section view of an exemplary substrate processing apparatus taken along the line I-Iʹ in FIG. 17, consistent with some embodiments of the present disclosure.

FIG. 19 illustrates a schematic of a substrate processing apparatus, consistent with some embodiments of the present disclosure.

### DETAILED DESCRIPTION

Example embodiments of the present disclosure will now be described more fully with reference to the accompanying drawings, in which example embodiments are shown.

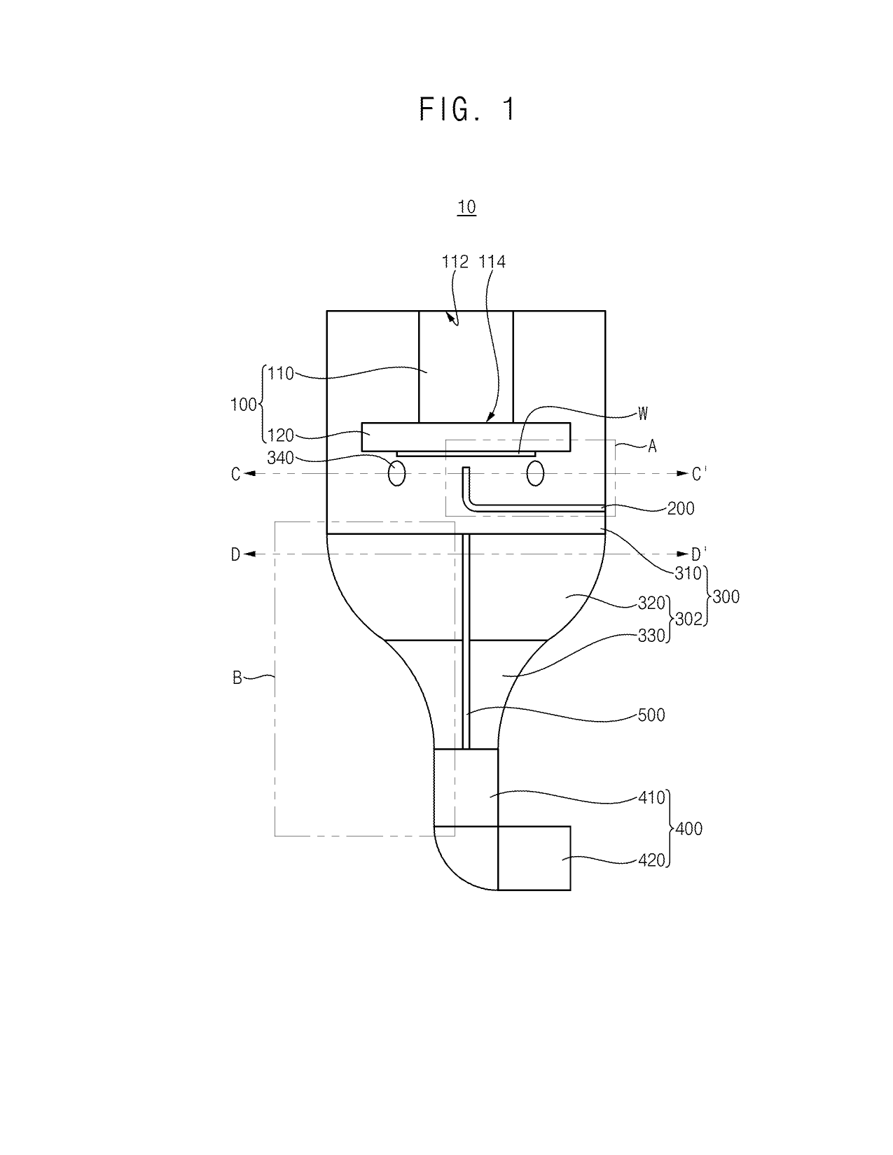

Referring to FIGS. 1 to 7, a substrate processing apparatus 10 may include a substrate support 100 configured to support a substrate W, a nozzle portion 200 configured to spray a cleaning fluid F onto the substrate W, a chamber 300 configured to receive the substrate support 100, and an exhaust duct 400 configured to exhaust the cleaning fluid F. Additionally, the substrate processing apparatus 10 may further include a rotational airflow prevention portion 500 configured to divide an internal space S of the chamber 300.

In some embodiments, the substrate processing apparatus 10 may be provided as a cleaning apparatus for cleaning a semiconductor substrate. The substrate processing apparatus 10 may be an apparatus that is configured to remove foreign substances on the semiconductor substrate by spraying a cleaning fluid F onto the semiconductor substrate. The cleaning fluid F may include a cleaning liquid such as water or a cleaning gas such as carbon dioxide gas.

In some embodiments, the substrate support 100 may include a shaft 110 and a substrate stage 120 connected to a lower end portion 114 of the shaft 110.

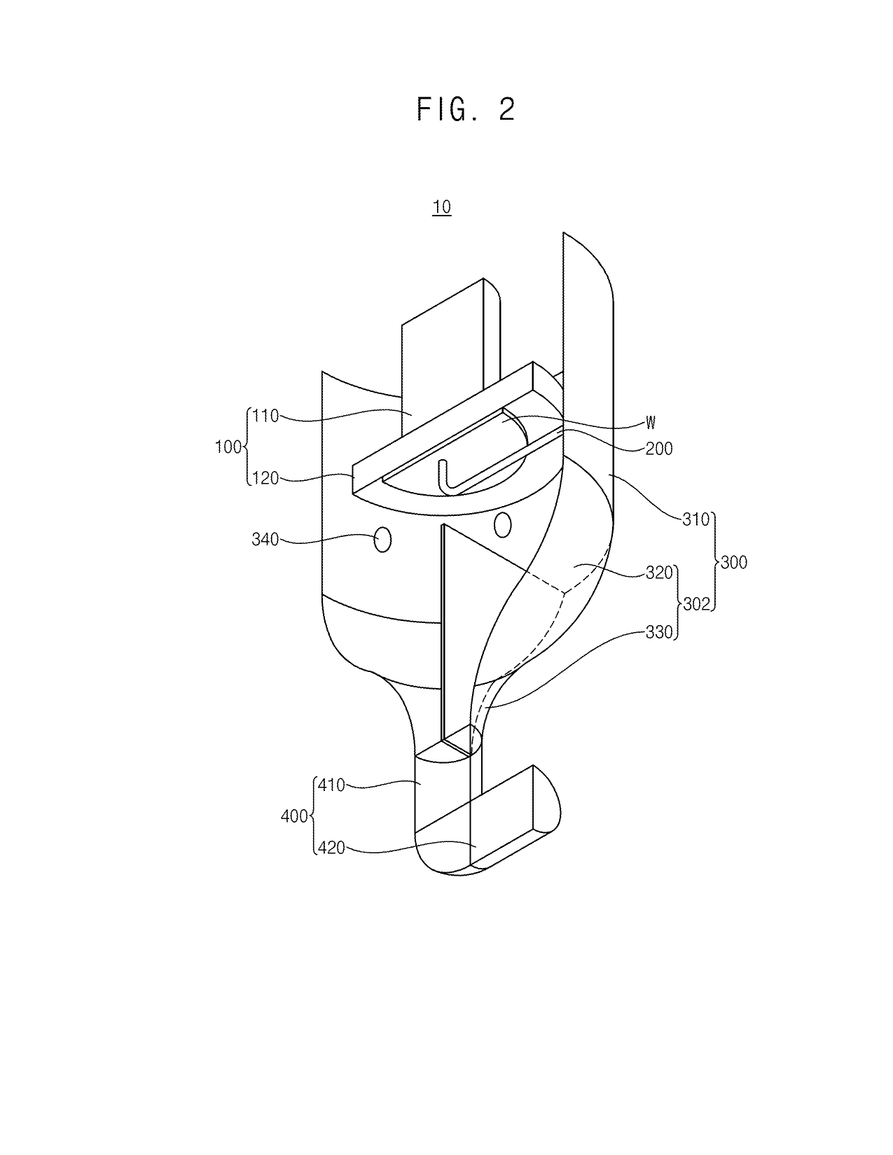

As illustrated in FIGS. 1 and 2, the shaft 110 may extend in a vertical direction in a rod shape, and may have an upper end portion 112 and the lower end portion 114 opposite to the upper end portion 112. The shaft 110 may have a shape such as a cylindrical shape, a hexagonal rod shape, an octagonal rod shape, etc., but is not limited thereto. The substrate stage 120 may have a seating surface 122. The substrate W may be adsorbed and supported on the seating surface 122 of the substrate stage 120. The substrate stage 120 may be disposed on the lower end portion 114 of the shaft 110 such that the seating surface 122 faces downward. Although not illustrated in the figures, the shaft 110 may be connected to a driving motor that rotates the shaft 110 and may rotate the substrate stage 120 with a rotational force transmitted by the driving motor.

The substrate W may be placed on the seating surface 122 of the substrate stage 120. The substrate W may include a glass substrate, a semiconductor substrate, a wafer, or the like. Although not illustrated in the figures, the substrate W may be adsorbed and fixedly supported on the seating surface 122 of the substrate stage 120 by an electrostatic force by an RF electrode disposed inside the substrate stage 120. Alternatively, the substrate W may be adsorbed and fixedly supported on the seating surface 122 of the substrate stage 120 by a vacuum adsorption force. Alternatively, the substrate W may be physically fixed on the seating surface 122 of the substrate stage 120 through a substrate holder disposed on the substrate stage 120.

In example embodiments, the nozzle portion 200 may include a nozzle head 210 and a supply pipe 220.

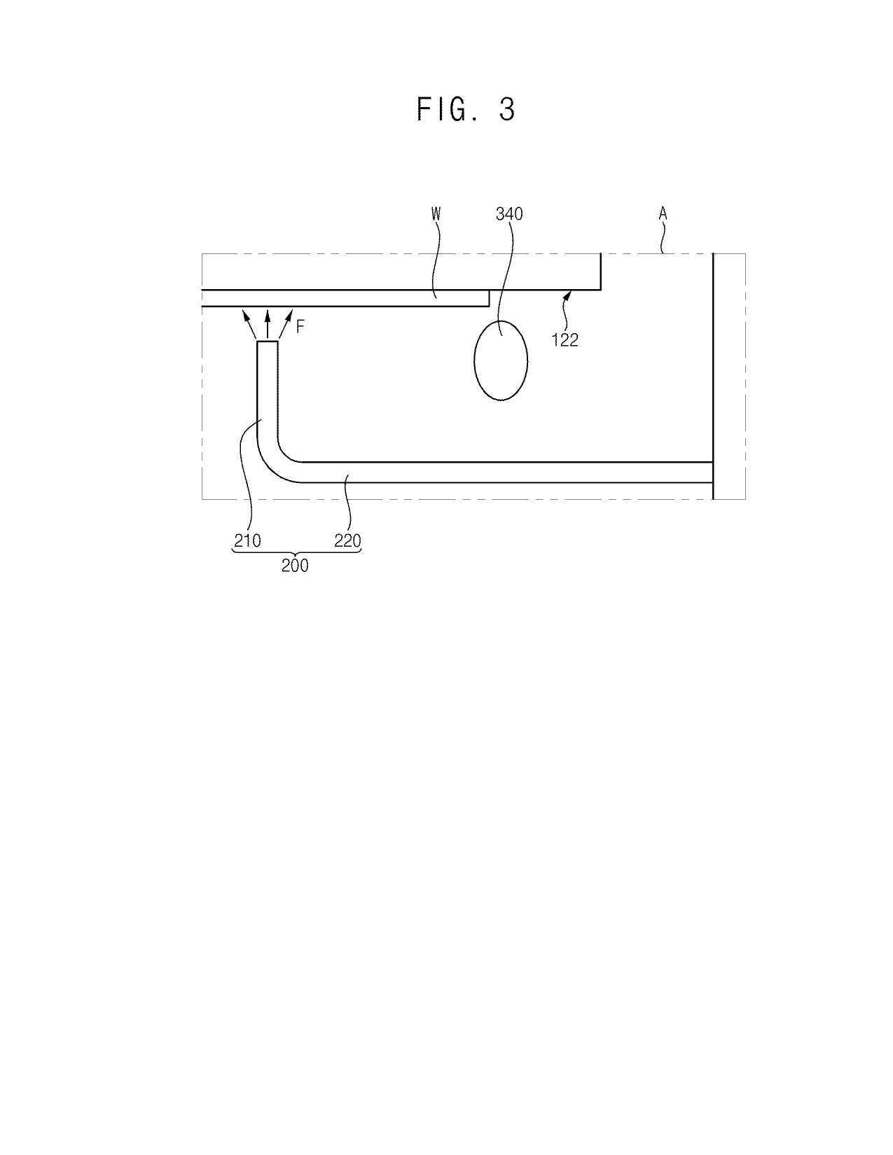

As illustrated in FIG. 3, the nozzle head 210 may be in fluid communication with the supply pipe 220. The supply pipe 220 may supply a cleaning fluid F to the nozzle head 210. The nozzle head 210 may spray the cleaning fluid F in a direction facing the seating surface 122 of the substrate stage 120. That is, the nozzle head 210 may be arranged in a direction facing upward.

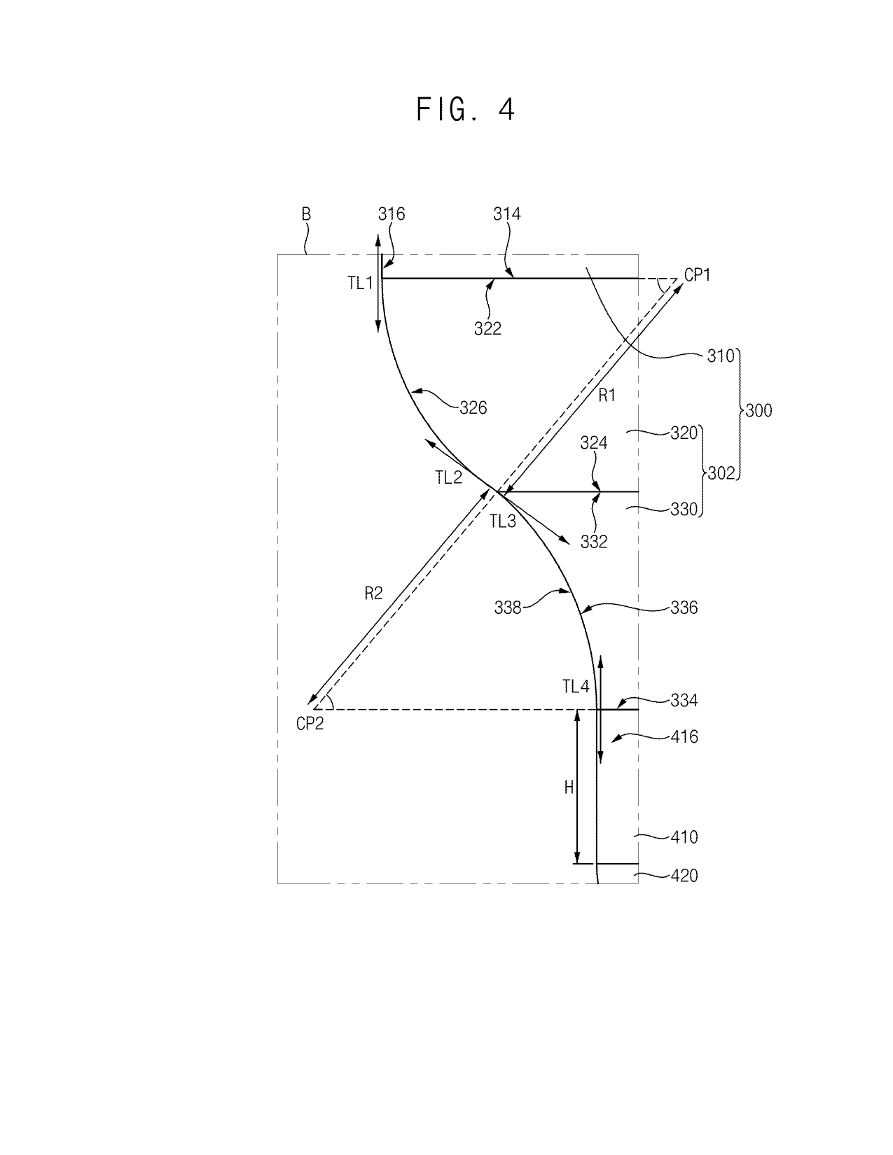

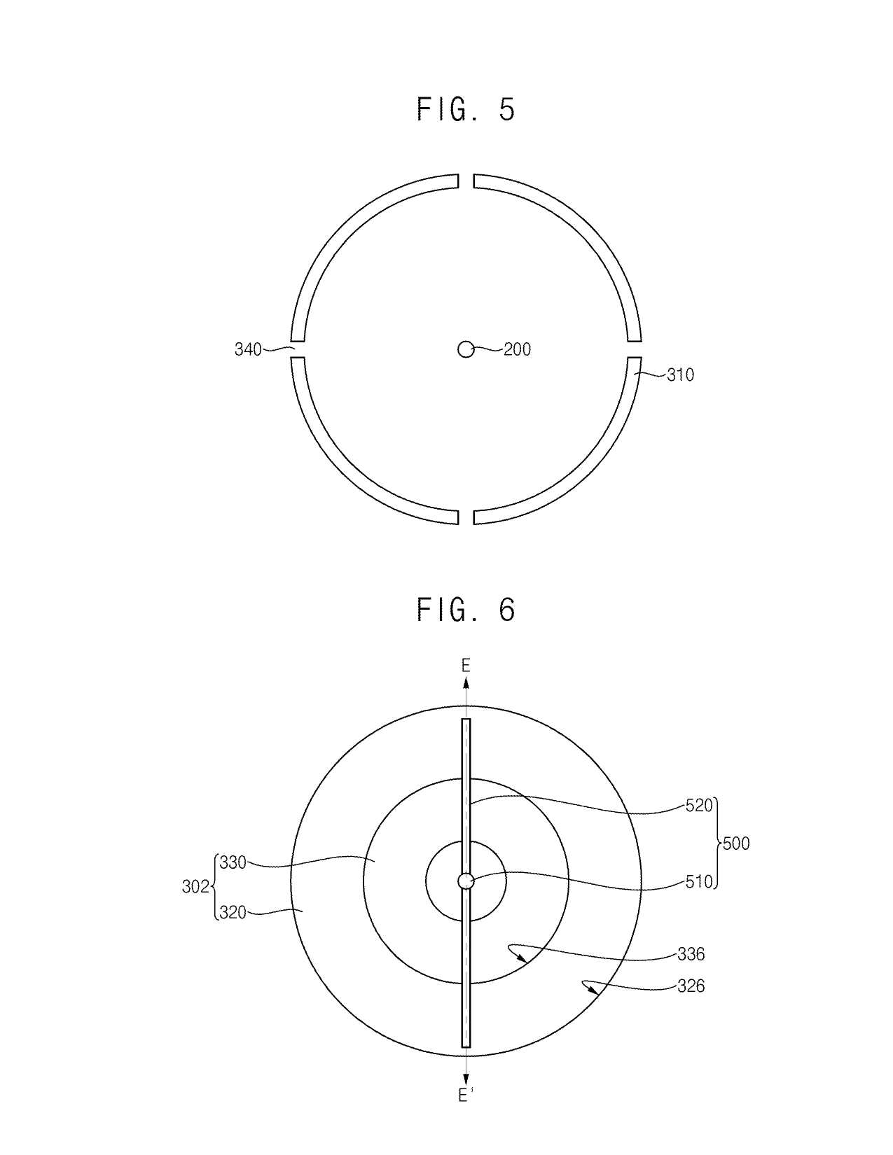

In some embodiments, as illustrated in FIG. 4, the chamber 300 may include a body portion 310 and a curved surface portion 302. The curved surface portion 302 may include a first curved surface portion 320 and a second curved surface portion 330. Additionally, the chamber 300 may further include at least one exhaust hole 340 (shown in FIG. 5) formed in the body portion 310.

The body portion 310 may have a cylindrical shape to surround the substrate support 100, and may have an upper surface 312 and a lower surface 314 facing the upper surface 312. The body portion 310 may vertically extend downward with a uniform cross-sectional shape to surround the substrate support 100 and the nozzle portion 200. In some embodiments, a cross-sectional shape of the upper surface 312 and a cross-sectional shape of the lower surface 314 may be constant, but are not limited thereto. The uniform cross-sectional shape of the body portion 310 may include a shape such as a circle, a square, a hexagon, or the like. For example, the body portion 310 may extend in a cylindrical shape, a square pillar shape, or a hexagonal pillar shape. The body portion 310 may be coupled with the substrate support 100 and the nozzle portion 200 to stably support the substrate support 100 and the nozzle portion 200.

As illustrated in FIG. 4, the curved surface portion 302 be connected to the body portion 310 and may have a shape that decreases as the curved surface portion 302 vertically extends downward. The first curved surface portion 320 may extend downward from the lower surface 314 of the body portion 310. The first curved surface portion 320 may have a shape of which a cross-sectional area gradually decreases as the first curved surface portion 320 vertically extends downward. A cross-section of the first curved surface portion 320 may have a circular shape. The first curved surface portion 320 may extend such that at least a portion of an inner circumferential surface 326 is spaced apart from a first central point CP1 by a predetermined distance when viewed in a cross-sectional view. In some embodiments, at least a portion of the first curved surface portion 320 may have a shape like a portion of a sphere. The first curved surface portion 320 may have a first radius of curvature R1. The first radius of curvature R1 may correspond to the distance from the first central point CP1 to the inner circumferential surface 326 of the first curved surface portion 320, that is, a radius of the sphere.

The first curved portion 320 may have an upper surface 322 and a lower surface 324 facing the upper surface 322. The upper surface 322 of the first curved portion 320 may extend to be in contact with the lower surface 314 of the body portion 310. The first curved portion 320 may have a first tangent line TL1 at the upper surface 322. The first tangent line TL1 may correspond to a tangent line that is perpendicular to an extension line extending from the first central point CP1 to the upper surface 322 of the first curved surface portion 320. The first curved surface portion 320 may be disposed on the lower surface 314 of the body portion 310 such that the first tangent line TL1 is positioned on a side surface 316 of the body portion 310. In some embodiments, the body portion 310 and the first curved surface portion 320 may be coupled without forming angles with each other.

The second curved portion 330 may extend downward from the lower surface 324 of the first curved portion 320. The second curved portion 330 may have a shape in which a cross-sectional area gradually decreases as the second curved portion 330 vertically extends downward. The cross-section may have a circular shape. The second curved portion 330 may extend such that at least a portion of an outer circumferential surface 338 is spaced apart from a second central point CP2 by a predetermined distance when viewed in a cross-sectional view. The second curved portion 330 may have a second radius of curvature R2. The second radius of curvature R2 may correspond to the distance from the second central point CP2 to the outer circumferential surface 338 of the second curved portion 330.

The second curved portion 330 may have an upper surface 332 and a lower surface 334 facing the upper surface 332. The upper surface 332 of the second curved portion 330 may extend to be in contact with the lower surface 324 of the first curved portion 320. The first curved portion 320 may have a second tangent line TL2 at the lower surface 324. The second curved portion 330 may have a third tangent line TL3 at the upper surface 332. The second tangent line TL2 may correspond to a tangent line that is perpendicular to an extension line extending from the first central point CP1 to the lower surface 324 of the first curved portion 320. The third tangent line TL3 may correspond to a tangent line that is perpendicular to an extension line extending from the second central point CP2 to the upper surface 332 of the second curved portion 330. The second curved portion 330 may be arranged on the lower surface 324 of the first curved portion 320 such that the third tangent line TL3 is parallel to the second tangent line TL2. That is, the first curved portion 320 and the second curved portion 330 may have a common tangent line at a point where the lower surface 324 of the first curved portion 320 and the upper surface 332 of the second curved portion 330 are in contact with each other. Accordingly, the first curved surface portion 320 and the second curved surface portion 330 may be coupled without forming angles to with each other.

As the first curved portion 320 is coupled to the body portion 310 such that the first tangent line TL1 is placed on the side surface 316 of the body portion 310, and the second curved portion 330 is coupled to the first curved portion 320 such that the second tangent line TL2 and the third tangent line TL3 are parallel to each other, a structure formed by the body portion 310, the first curved portion 320, and the second curved portion 330 may provide a non-angular streamlined internal structure. Accordingly, as described below, since a possibility of forming a laminar flow without generating turbulence when discharging the cleaning fluid may be increased, the cleaning fluid may be prevented from being re-dispersed due to an unstable airflow.

In some embodiments, the body portion 310 may include the at least one exhaust hole 340 disposed on the side surface 316. The exhaust hole 340 may provide negative pressure inside the body portion 310 and may exhaust the cleaning fluid F and foreign substances through the negative pressure.

In some embodiments, the exhaust hole 340 may be disposed on the side surface 316 of the body 310 to exhaust the cleaning fluid F and the foreign substances generated from the substrate W. The at least one exhaust hole 340 may have a circular shape, but is not limited thereto. The at least one exhaust hole 340 may be arranged at a height between the substrate stage 120 and the nozzle head 210 that sprays the cleaning fluid F onto the substrate W. Accordingly, the at least one exhaust hole 340 may effectively exhaust the cleaning fluid F and the foreign substances after cleaning is completed, to thereby prevent the foreign substances from being re-dispersed on the substrate W.

As illustrated in FIG. 5, the exhaust hole 340 may include a plurality of exhaust holes 340 that are spaced apart from each other along the side surface 316 of the body portion 310. As illustrated in FIG. 5, the exhaust holes 340 may be arranged on the side surface 316 of the body portion 310 at regular intervals. For example, four exhaust holes 340 may be spaced apart from each other with a central angle of 90 degrees, but number of the exhaust holes 340 is not limited thereto.

In some embodiments, the exhaust duct 400 may include a first duct 410 and a second duct 420. The exhaust duct 400 may provide a negative pressure inside the chamber 300 to exhaust the cleaning fluid F and foreign substances through the negative pressure.

The first duct 410 may extend downward from the lower surface 334 of the second curved portion 330. The second curved portion 330 may have a fourth tangent line TL4 at the lower surface 334. The fourth tangent line TL4 may correspond to a tangent line that is perpendicular to an extension line extending from the second central point CP2 to the lower surface 334. The first duct 410 may be arranged on the lower surface 334 of the second curved portion 330 such that the fourth tangent line TL4 is placed on the side surface 416 of the first duct 410. That is, the second curved portion 330 and the first duct 410 may be coupled without forming angles with each other.

In some embodiments, the second duct 420 may be connected to the first duct 410. The second duct 420 may extend perpendicularly to the first duct 410. For example, the first duct 410 and the second duct 420 may extend to have a certain cross-sectional shape. The cross-sectional shapes of the first duct 410 and the second duct 420 may include shapes such as a circle, a square, a hexagon, etc., but are not limited thereto.

In some embodiments, the rotational airflow prevention portion 500 may be disposed to partition at least a portion of the internal space surrounded by the body portion 310, the first curved portion 320, and the second curved portion 330 within the chamber 300.

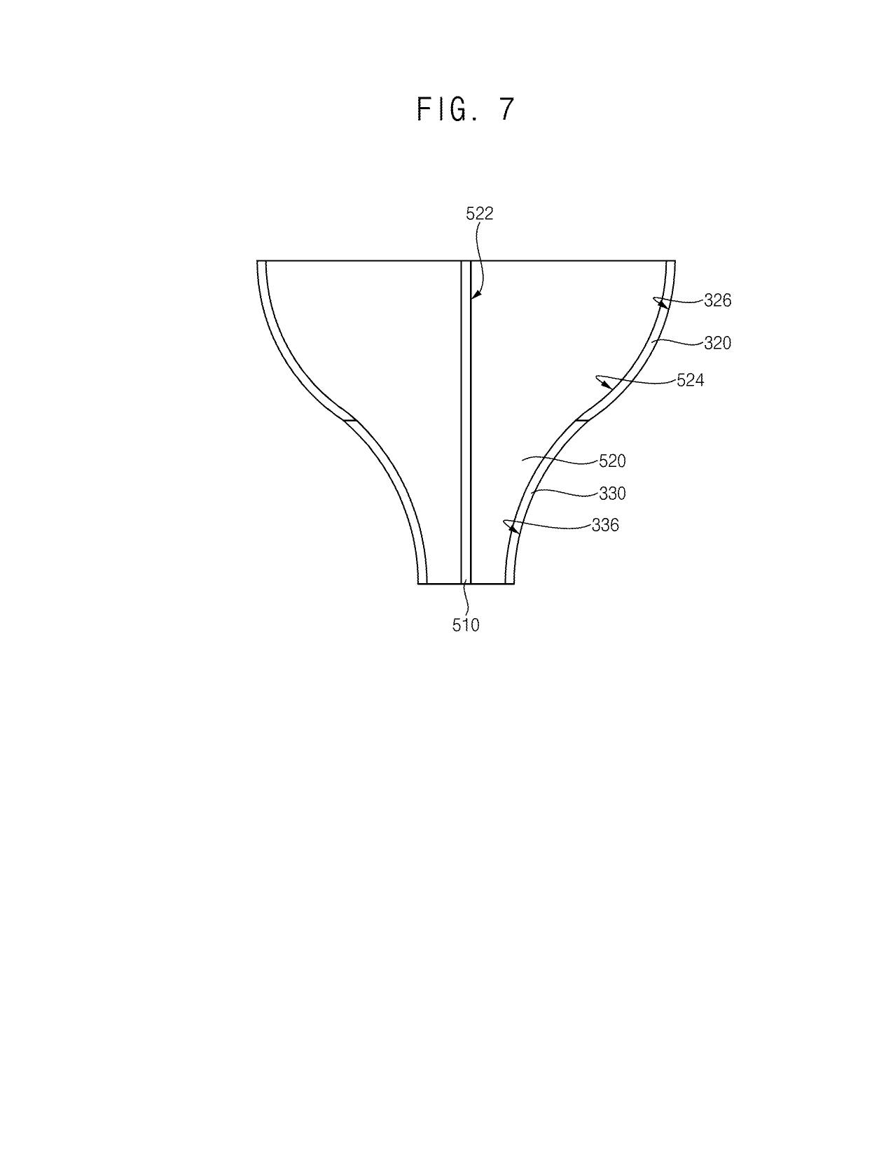

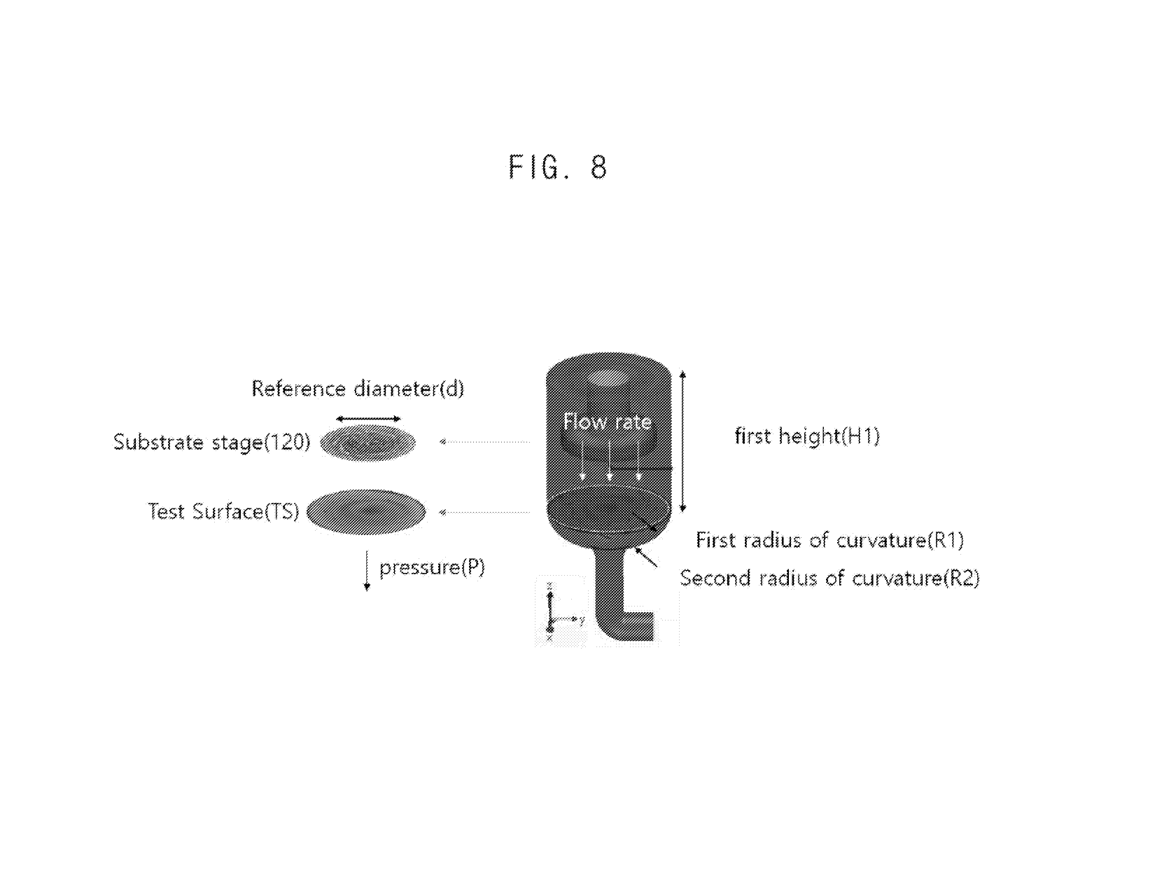

As illustrated in FIGS. 6 and 7, the rotational airflow prevention portion 500 may include a center rod 510 and a plurality of planar plates 520. The center rod 510 may extend vertically downward within the chamber 300. For example, the center rod 510 may be arranged to extend from the same height as the upper surface 322 of the first curved portion 320 to the same height as the lower surface 334 of the second curved portion 330. The center rod 510 may be arranged to extend from the central point of the inner circumferential surface of the first curved portion 320.

In some embodiments, the plurality of planar plates 520 may extend vertically downward from the center rod 510, as shown in FIG. 7. The plurality of planar plates 520 may extend in a direction away from the center rod 510, in a direction toward the inner circumferential surface 326 of the first curved portion 320 or toward the inner circumferential surface 336 of the second curved portion 330. Each of the plurality of planar plates 520 may have an inner surface 522 and an outer surface 524 opposite to the inner surface 522. The plurality of planar plates 520 may be arranged such that the inner surface 522 is connected to the center rod 510. The outer surface 524 may extend along a profile of the inner circumferential surface 326 of the first curved portion 320 and a profile of an inner circumferential surface 336 of the second curved portion 330. The outer surface 524 may extend to be spaced apart from the inner circumferential surface 326 of the first curved portion 320 and the inner circumferential surface 336 of the second curved portion 330 by a predetermined distance.

The plurality of planar plates 520 may be arranged to be spaced apart from each other on the center rod 510. For example, two planar plates 520 may be arranged to be spaced apart from each other to have a center angle of 180 degrees. The plurality of planar plates 520 may prevent a rotational airflow from occurring while passing through the first curved portion 320 and the second curved portion 330 when the cleaning fluid F and the foreign substances are exhausted during the cleaning process, and thus, it may prevent the foreign substances from being ineffectively exhausted or re-dispersed onto the substrate.

As described above, the substrate processing apparatus 10 may include the substrate support 100, the nozzle portion 200 configured to spray the cleaning fluid F onto the substrate W on the substrate support 100, the chamber 300 configured to receive the substrate support 100, the plurality of exhaust holes 340 disposed in the body portion 310 of the chamber 300, the exhaust duct 400 configured to exhaust the cleaning fluid F and foreign substances, and the rotational air flow prevention portion 500 configured to partition the internal space S of the chamber 300.

In the substrate processing apparatus 10, consistent with some embodiments, the substrate W may be placed on the substrate support 100 such that the surface of the substrate W to be cleaned faces downward, and the nozzle head 210 of the nozzle portion 200 may spray the cleaning fluid F in a direction from the bottom to the top toward the surface of the substrate. Additionally, the exhaust holes 340 may be arranged to surround the body 310 of the chamber 300 at a height at which the nozzle head 210 for spraying the cleaning fluid F is arranged, the exhaust duct 400 may be arranged at a lower portion of the chamber 300, and the rotational air flow prevention portion 500 may be arranged inside the chamber 300. Accordingly, the cleaning fluid F and the foreign substances may be primarily exhausted from the plurality of exhaust holes 340, flow to the lower surface of the chamber 300, and be exhausted to the exhaust duct 400 without generating a rotational air flow by the rotational air flow prevention portion 500. Thus, compared to related art in which the cleaning fluid is sprayed downward on the semiconductor substrate, it may be possible to effectively prevent the phenomenon in which foreign substances generated during cleaning being re-dispersed onto the semiconductor substrate.

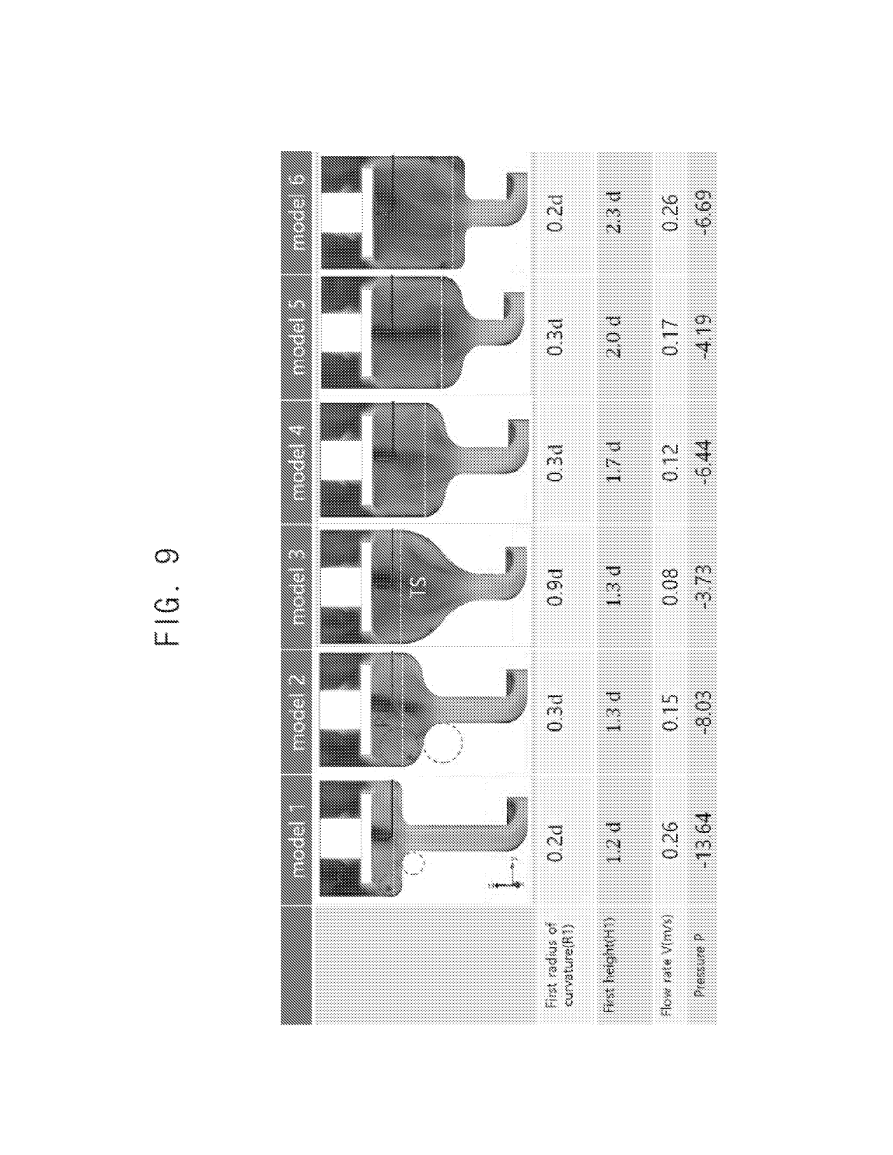

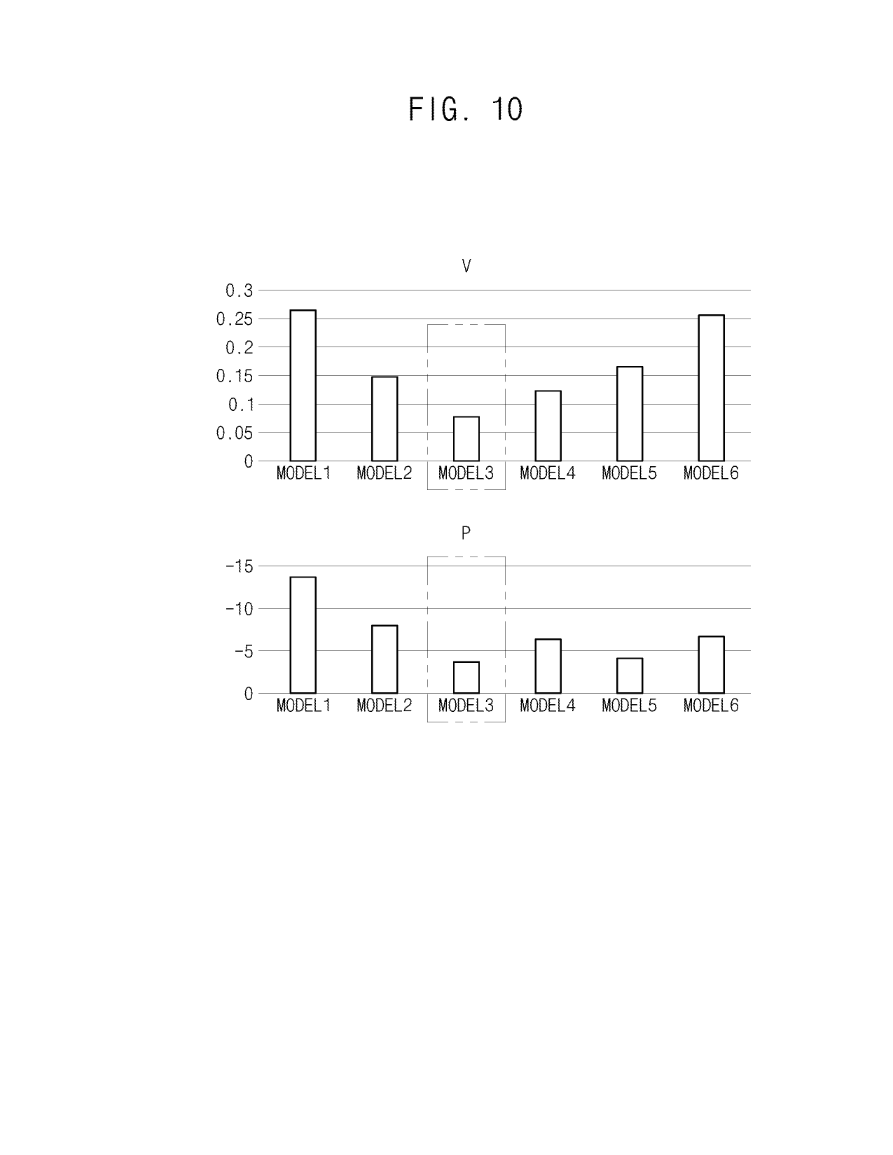

FIGS. 8 to 10 illustrate views and data plots explaining results of flow analysis for a substrate processing apparatus, consistent with some embodiments of the present disclosure. FIG. 8 illustrates a test surface that serves as a reference for flow analysis for a substrate processing apparatus. FIG. 9 illustrates a table of results of flow analysis for a substrate processing apparatus, consistent with some embodiments of the present disclosure. FIG. 10 illustrates a graph of results of flow analysis for a substrate processing apparatus, consistent with some embodiments of the present disclosure.

Referring to FIGS. 8 to 10, flow analysis for the substrate processing apparatus 10 may be performed.

As illustrated in FIG. 8, the body portion 310 of the chamber 300 of the substrate processing apparatus 10 may extend to have a first height H1 and a first diameter D1. The first height H1 may be a height from the top surface 312 to the bottom surface 314 of the body portion 310. The substrate stage 120 may have a reference diameter d. The reference diameter d may be a reference value for dimensionlessly transforming various values when analyzing various values that have an optimal efficiency in exhausting the cleaning fluid F and foreign substances by the substrate processing apparatus 10. For example, the reference diameter d may be 300 μm, but is not limited thereto.

Referring again to FIG. 4, the first curved portion 320 may extend in a convex shape outwardly such that the inner circumferential surface 326 has a first radius of curvature R1. The second curved portion 330 may extend in a convex shape inwardly such that the outer circumferential surface 338 has a second radius of curvature R2. The first radius of curvature R1 and the second radius of curvature R2 may be assumed to have the same numerical value when performing the flow analysis for the substrate processing apparatus 10.

A test surface TS may correspond to a virtual plane that serves as a reference for measuring a pressure P inside the chamber 300 and a flow rate Vxy of the cleaning fluid F. The position of the test surface TS may correspond to a point where the curved surface of the chamber 300 begins, that is, a point where the body portion 310 of the chamber 300 and the first curved surface portion 320 are connected. For example, the position may correspond to the lower surface 314 of the body portion 310 or the upper surface 322 of the first curved surface portion 320. The lower the flow rate Vxy of the cleaning fluid F on the test surface TS, the less likely it is that the foreign substance will be re-dispersed onto the substrate W, which is advantageous. The higher the pressure P, the greater the pressure difference from the negative pressure provided by the exhaust duct 400, which may be advantageous because the exhaust efficiency increases.

As shown in FIG. 9, the flow analysis may be performed through six embodiments in which the values of the first radius of curvature R1 and the first height H1 are adjusted differently.

When performing the flow analysis to find an embodiment having an optimal exhaust efficiency by changing the structure of the substrate processing apparatus 10, the total height from the chamber 300 to the exhaust duct 400 of the substrate processing apparatus 10 may be maintained constant, and computational fluid dynamics CFD may be performed by changing only the values of the first radius of curvature R1 and the first height H1.

The value of the first curvature radius R1 may be within a range of 0.2 to 0.9 times the reference diameter d and the value of the first height H1 may be within a range of 1.2 to 2.3 times the reference diameter d. A first embodiment (model 1) may be a flow analysis result in which the value of the first curvature radius R1 is set to 0.2 times the reference diameter d and the value of the first height H1 is set to 1.2 times the reference diameter d. A second embodiment (model 2) may be a flow analysis result in which the value of the first curvature radius R1 is set to 0.3 times the reference diameter d and the value of the first height H1 is set to 1.3 times the reference diameter d. A third embodiment (model 3) may be a flow analysis result in which the value of the first curvature radius R1 is set to 0.9 times the reference diameter d and the value of the first height H1 is set to 1.3 times the reference diameter d. A fourth embodiment (model 4) may be a flow analysis result in which the value of the first curvature radius R1 is set to 0.3 times the reference diameter d and the value of the first height H1 is set to 1.7 times the reference diameter d. A fifth embodiment (model 5) may be a flow analysis result in which the value of the first curvature radius R1 is set to 0.3 times the reference diameter d and the value of the first height H1 is set to 2.0 times the reference diameter d. A sixth embodiment (model 6) may be a flow analysis result in which the value of the first curvature radius R1 is set to 0.2 times the reference diameter d and the value of the first height H1 is set to 2.3 times the reference diameter d.

The flow rate Vxy may be a variable for measuring a flow rate of the cleaning fluid F and the foreign substances, and the analysis may be performed by applying a weight of foreign substance molecules having a size of 5 μm or less. The pressure P may correspond to a value obtained by measuring the pressure on the test surface TS.

As illustrated in FIG. 10, results of the flow analysis for the substrate processing apparatus 10 may be represented in graphs. In the third embodiment (model 3), the flow velocity Vxy is shown to be the lowest and the pressure P is shown to be the highest. Therefore, among several embodiments, when the value of the first radius of curvature R1 of the first curved portion 320 is 0.9 times the reference diameter d of the substrate stage 120, and the value of the first height H1 of the body portion 310 is 1.3 times the reference diameter d, it may be interpreted that this is the optimal structure for effectively exhausting the cleaning fluid F and the foreign substances and preventing the cleaning fluid F and the foreign substances from being re-dispersed onto the substrate W.

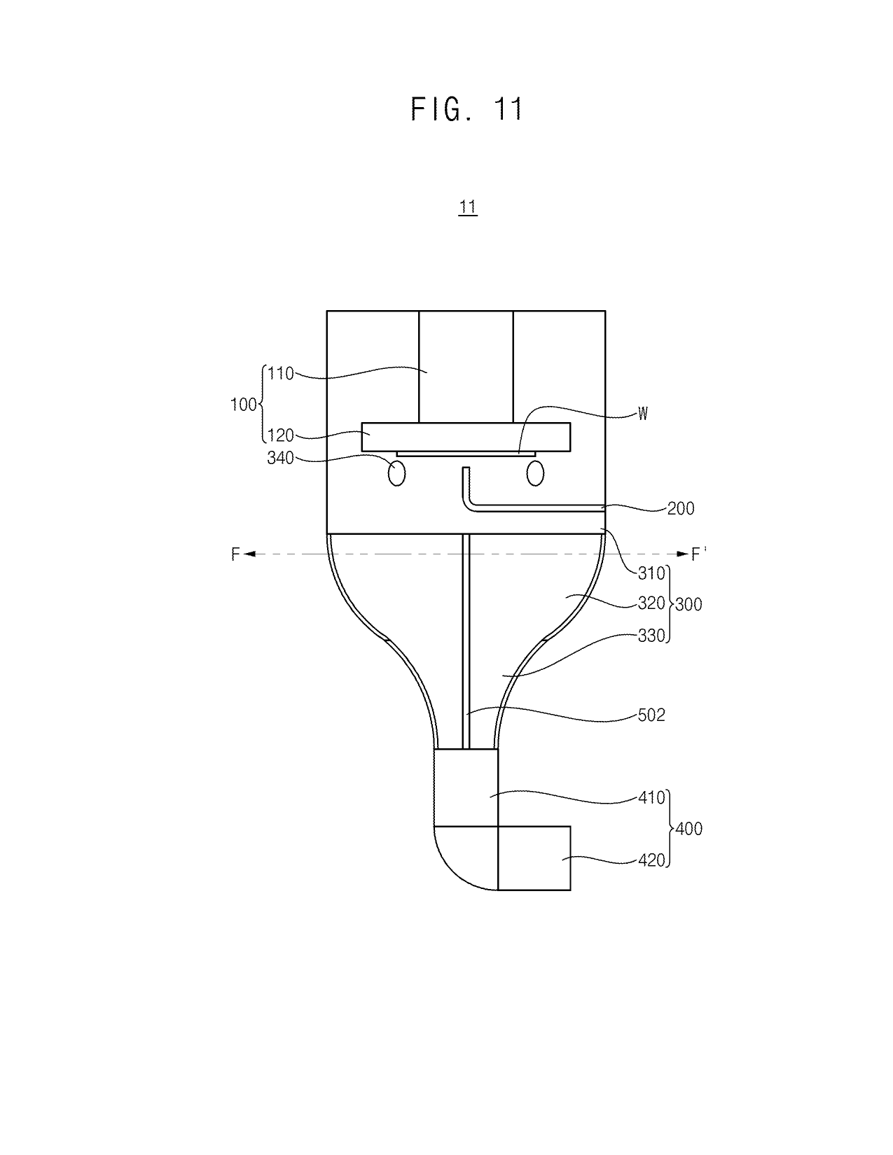

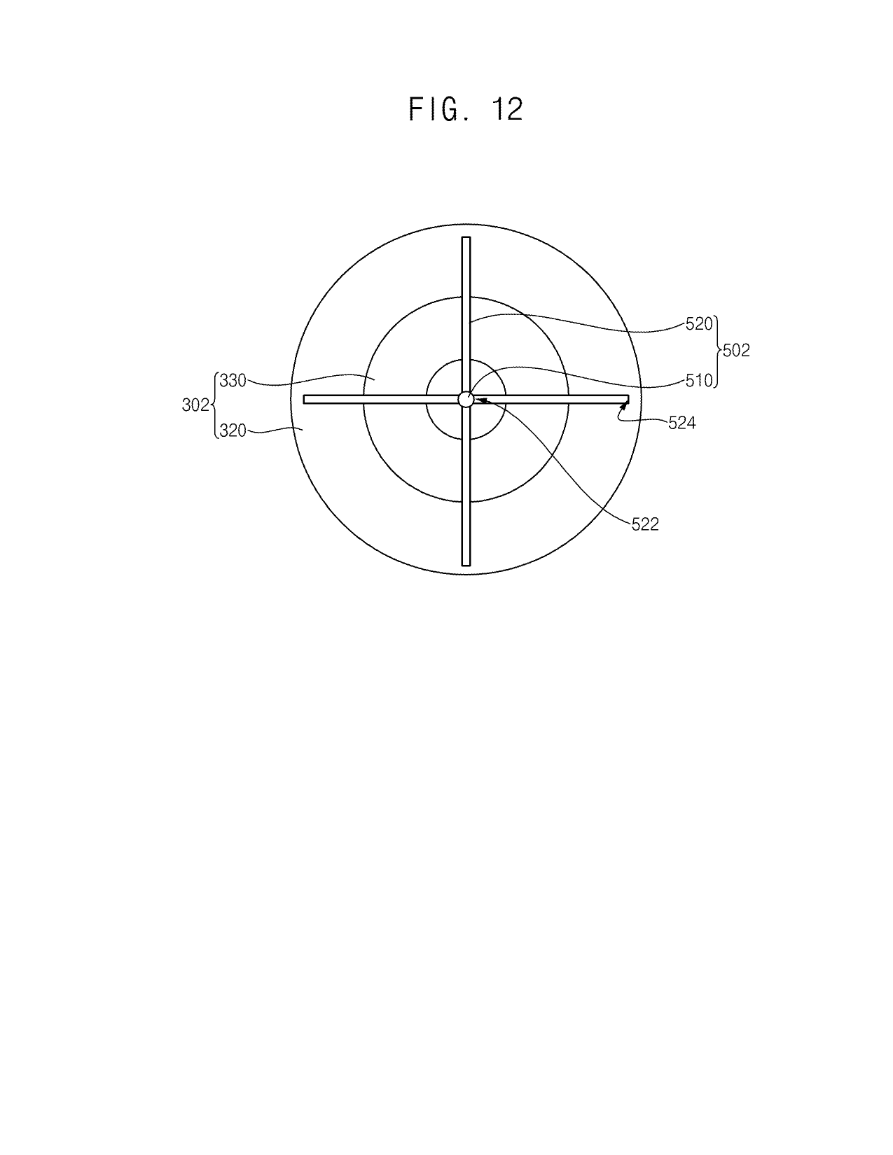

FIG. 11 illustrates a cross-sectional view of an exemplary substrate processing apparatus, consistent with some embodiments of the present disclosure, and FIG. 12 illustrates a cross-sectional view taken along the line F-Fʹ in FIG. 11.

The substrate processing apparatus 11 may include substantially the same components as those of the substrate processing apparatus described with reference to FIG. 1, except that a rotational airflow prevention portion 502 includes four planar plates 520. Accordingly, the same components are denoted by the same reference numerals, and repeated descriptions of the same components may be omitted.

Referring to FIGS. 11 and 12, a rotational airflow prevention portion 502 may include a center rod 510 and a plurality of planar plates 520.

The plurality of planar plates 520 may include four planar plates 520 that are arranged to be spaced apart from each other on the center rod 510. For example, the four planar plates 520 may be arranged to be spaced apart from each other to have a center angle of 90 degrees. The plurality of planar plates 520 may prevent a rotational airflow from occurring while passing through the first curved portion 320 and the second curved portion 330 when the cleaning fluid F and foreign substances are exhausted during the cleaning process, and thus, it may prevent the foreign substances from being ineffectively exhausted or from being re-dispersed onto the substrate.

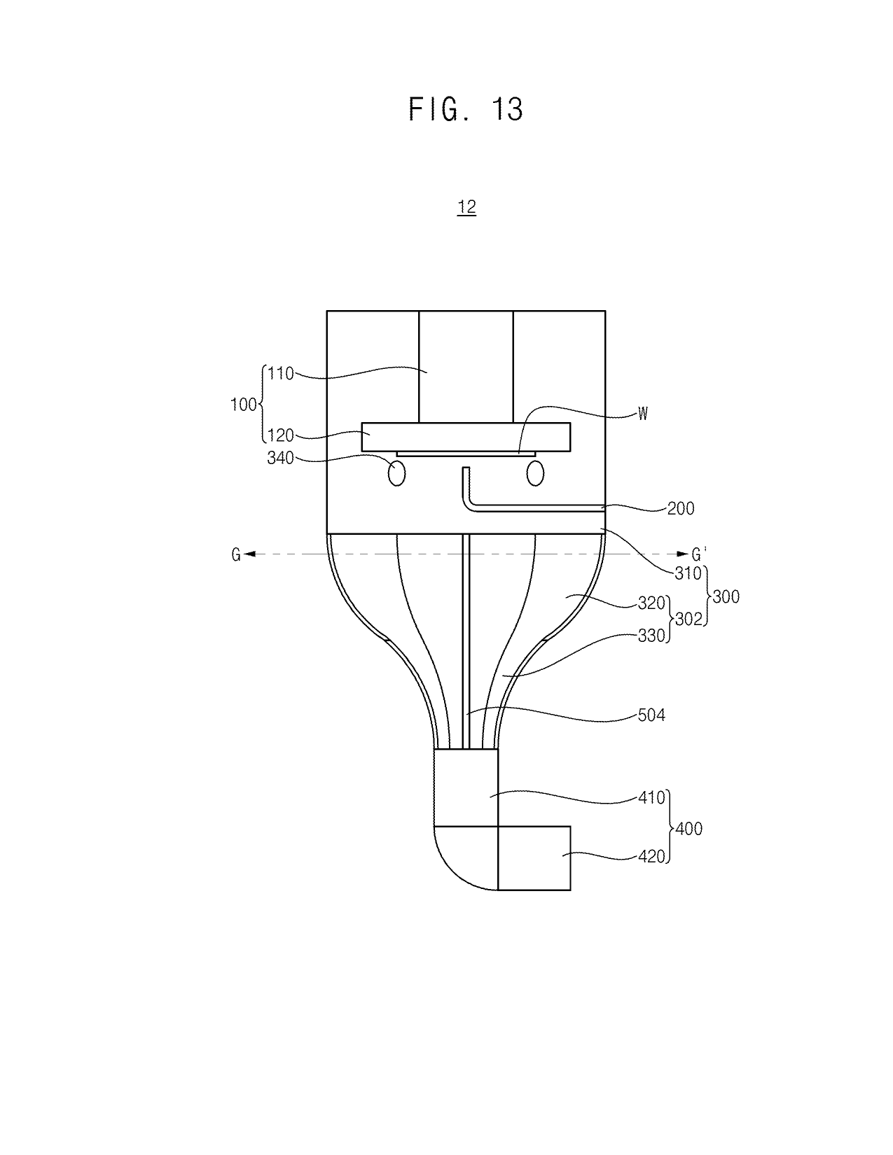

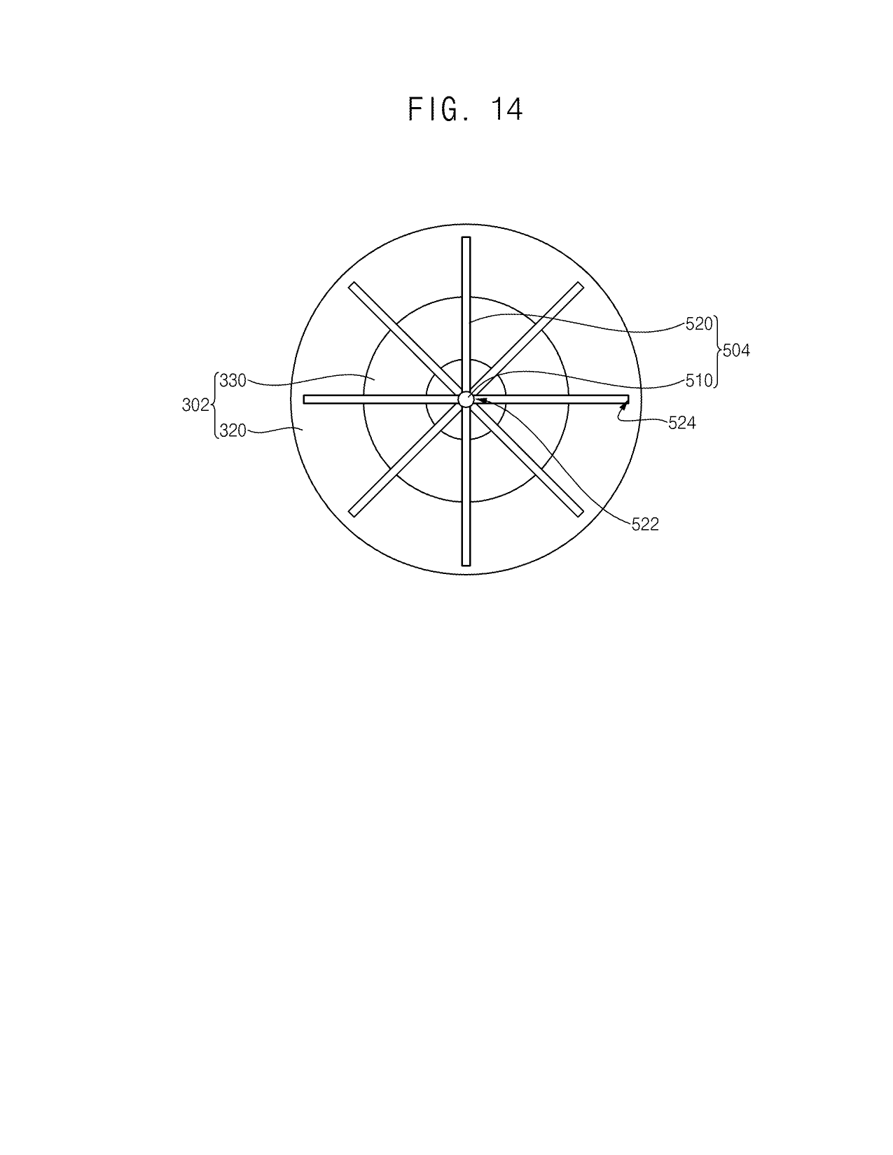

FIG. 13 illustrates a cross-sectional view of an exemplary substrate processing apparatus, consistent with some embodiments of the present disclosure. FIG. 14 illustrates a cross-sectional view taken along the line G-Gʹ in FIG. 14.

The substrate processing apparatus 12 may include substantially the same components as those of the substrate processing apparatus described with reference to FIG. 1, except that a rotational airflow prevention portion 504 includes eight planar plates 520. Accordingly, the same components are denoted by the same reference numerals, and repeated descriptions of the same components may be omitted.

Referring to FIGS. 13 and 14, a rotational airflow prevention portion 504 may include a center rod 510 and a plurality of planar plates 520.

The plurality of planar plates 520 may include eight planar plates 520 that are arranged to be spaced apart from each other on the center rod 510. For example, the eight planar plates 520 may be arranged to be spaced apart to have a center angle of 45 degrees. The plurality of planar plates 520 may prevent a rotational airflow from occurring when the cleaning fluid F and foreign substances are exhausted through the first curved portion 320 and the second curved portion 330 during the cleaning process, thereby preventing the foreign substances from being ineffectively exhausted or from being re-dispersed onto the substrate.

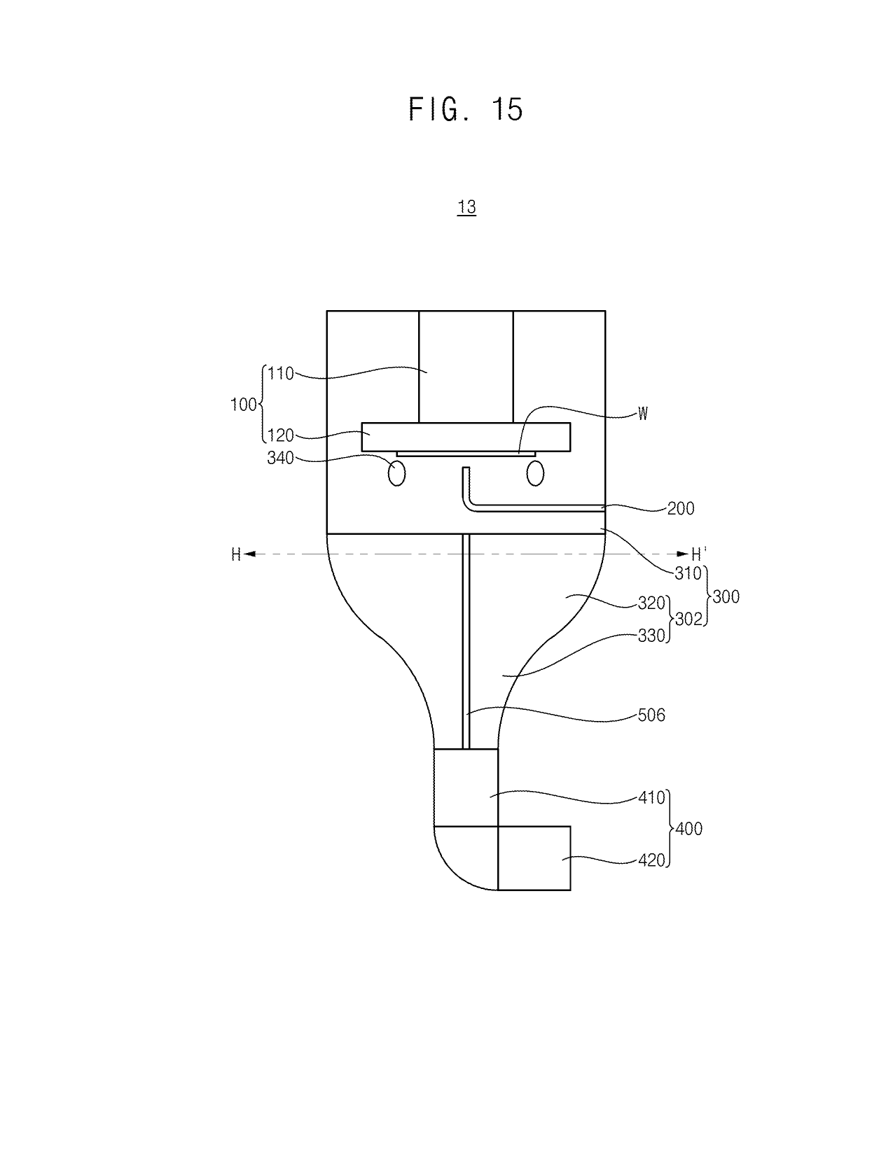

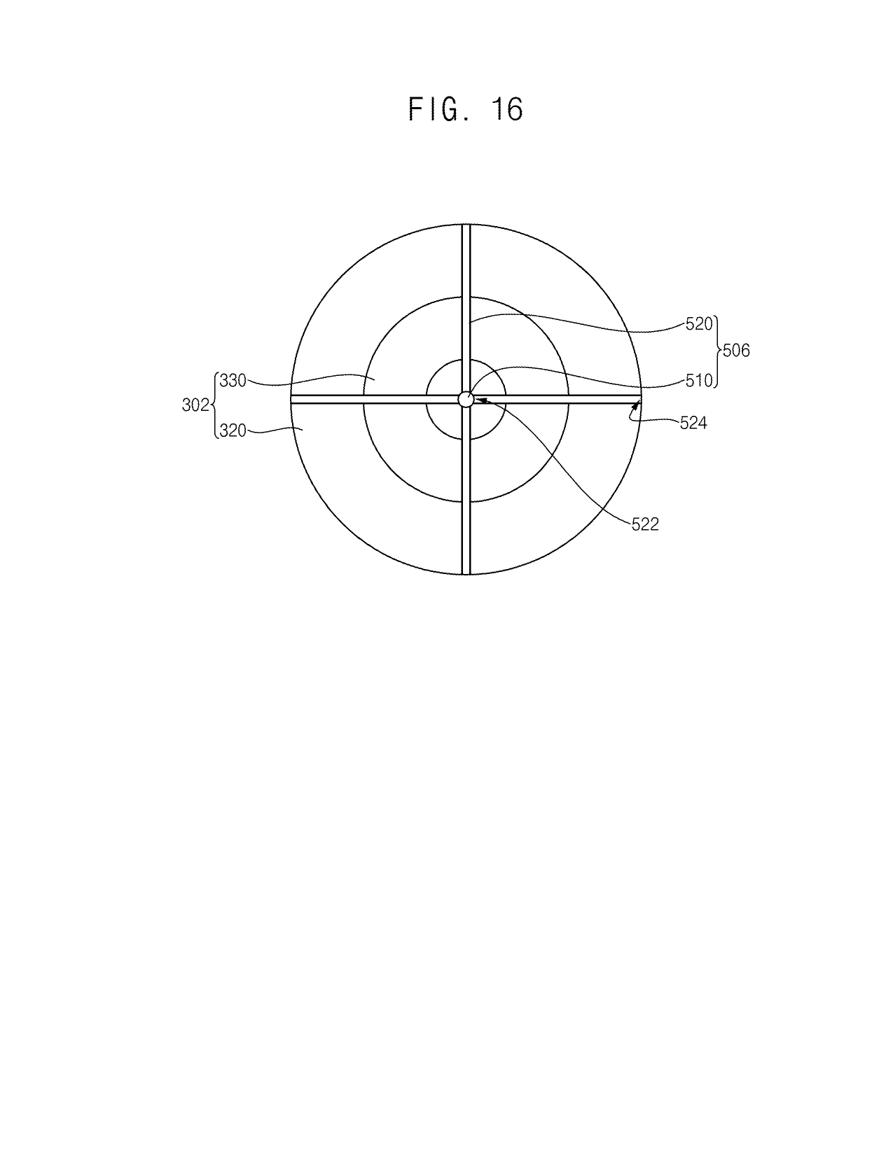

FIG. 15 is a cross-sectional view illustrating an exemplary substrate processing apparatus, consistent with some embodiments of the present disclosure, and FIG. 16 illustrates a cross-sectional view taken along the line H-Hʹ in FIG. 15.

The substrate processing apparatus 13 may include substantially the same components as those of the substrate processing apparatus shown in FIG. 1, except that the outer surfaces 524 of the planar plates 520 of the rotational airflow prevention portion 506 are not spaced apart from an inner circumferential surfaces 326 of a first curved portion 320 and an inner circumferential surfaces 336 of a second curved portion 330. Accordingly, the same components are denoted by the same reference numerals, and repeated descriptions of the same components may be omitted.

Referring to FIGS. 15 and 16, the rotational airflow prevention portion 506 may include a center rod 510 and a plurality of planar plates 520. Each of the plurality of planar plates 520 may have an inner surface 522 and an outer surface 524 opposite to the inner surface 522. The plurality of planar plates 520 may be arranged such that an inner surface 522 is connected to the center rod 510. The outer surface 524 may extend along a profile of an inner circumferential surface 326 of a first curved portion 320 and a profile of an inner circumferential surface 336 of a second curved portion 330. The outer surface 524 may be arranged to be connected to the inner circumferential surface 326 of the first curved portion 320 and the inner circumferential surface 336 of the second curved portion 330. Accordingly, the rotational airflow prevention portion 506 may divide an inner space provided by the first curved portion 320 and the second curved portion 330 into four spaces through the four planar plates 520. The plurality of planar plates 520 may prevent a rotational airflow from occurring when the cleaning fluid F and foreign substances are exhausted through the first curved portion 320 and the second curved portion 330 during the cleaning process, thereby preventing the foreign substances from being ineffectively exhausted or from being re-dispersed onto the substrate.

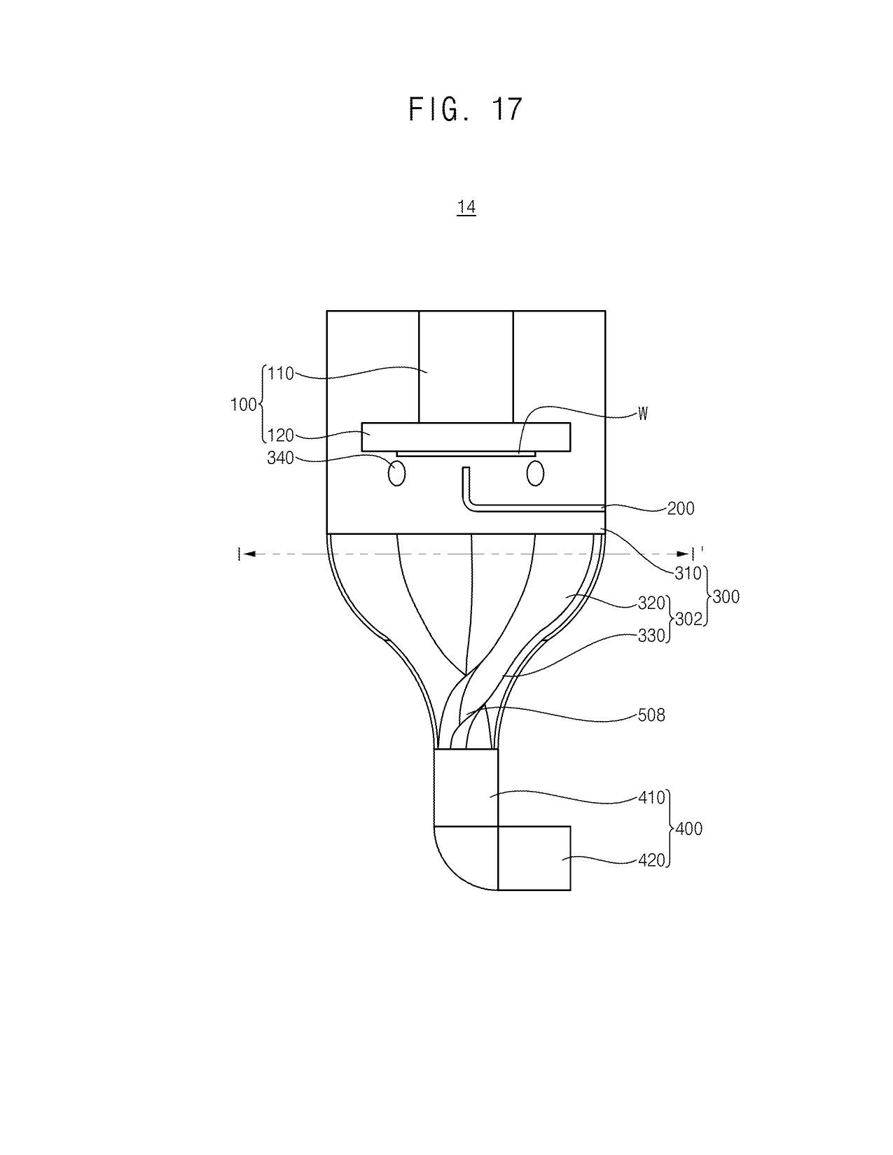

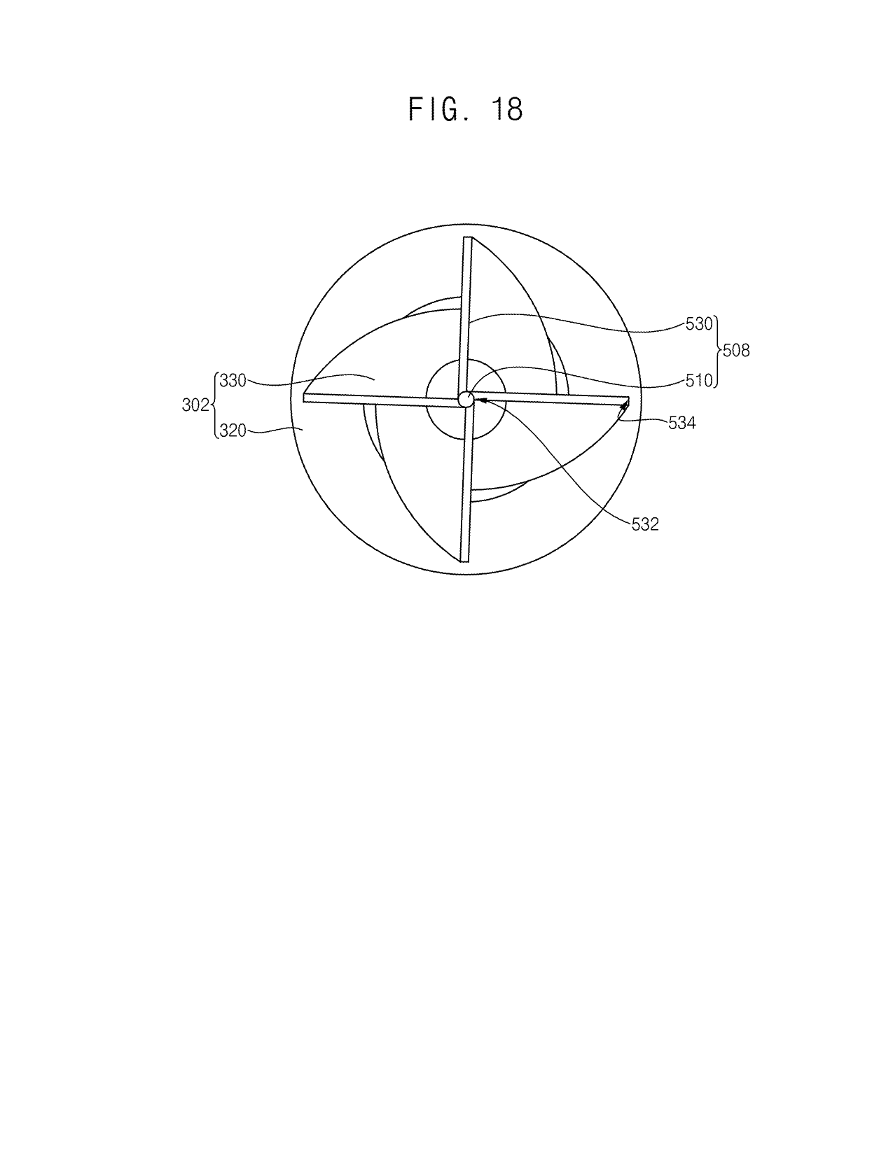

FIG. 17 is a cross-sectional view illustrating an exemplary substrate processing apparatus, consistent with some embodiments of the present disclosure, and FIG. 18 illustrates a cross-sectional view taken along the line I-Iʹ in FIG. 17.

The substrate processing apparatus 14 may include substantially the same components as those of the substrate processing apparatus described with reference to FIG. 1, except that a rotational airflow prevention portion 508 includes spiral plates 530. Accordingly, the same components are denoted by the same reference numerals, and repeated descriptions of the same components may be omitted.

Referring to FIGS. 17 and 18, a rotation airflow prevention portion 508 may include a center rod 510 and a plurality of spiral plates 530.

Each spiral plate 530 may extend downward on the center rod 510. For example, the spiral plate 530 may have a shape that extends downward so as to rotate and surround a side surface of the center rod 510. The plurality of spiral plates 530 may extend in a direction away from the center rod 510, that is, in a direction toward an inner circumferential surface 326 of a first curved portion 320 or toward an inner circumferential surface 336 of a second curved portion 330. Each of the plurality of spiral plates 530 may have an inner surface 532 and an outer surface 534 opposite to the inner surface 532. The plurality of spiral plates 530 may be arranged such that the inner surface 532 is connected to the center rod 510. The outer surface 534 may extend along a profile of the inner circumferential surface 326 of the first curved portion 320 and a profile of the inner circumferential surface 336 of the second curved portion 330. The outer surface 534 may extend to be spaced apart from the inner circumferential surface 326 of the first curved portion 320 and the inner circumferential surface 336 of the second curved portion 330 by a predetermined distance.

The plurality of spiral plates 530 may be arranged to be spaced apart from each other on the center rod 510. For example, the four spiral plates 530 may be arranged to be spaced apart from each other to have a center angle of 90 degrees. The spiral plates 530 may extend downward along the center rod 510 and extend spirally extend while maintaining the center angle of 90 degrees, and may be arranged to be spaced apart from each other. The plurality of planar plates 530 may serve to prevent a rotational airflow from occurring when the cleaning fluid F and foreign substances are exhausted through the first curved portion 320 and the second curved portion 330 during the cleaning process, thereby preventing the foreign substances from being ineffectively exhausted or from being re-dispersed onto the substrate.

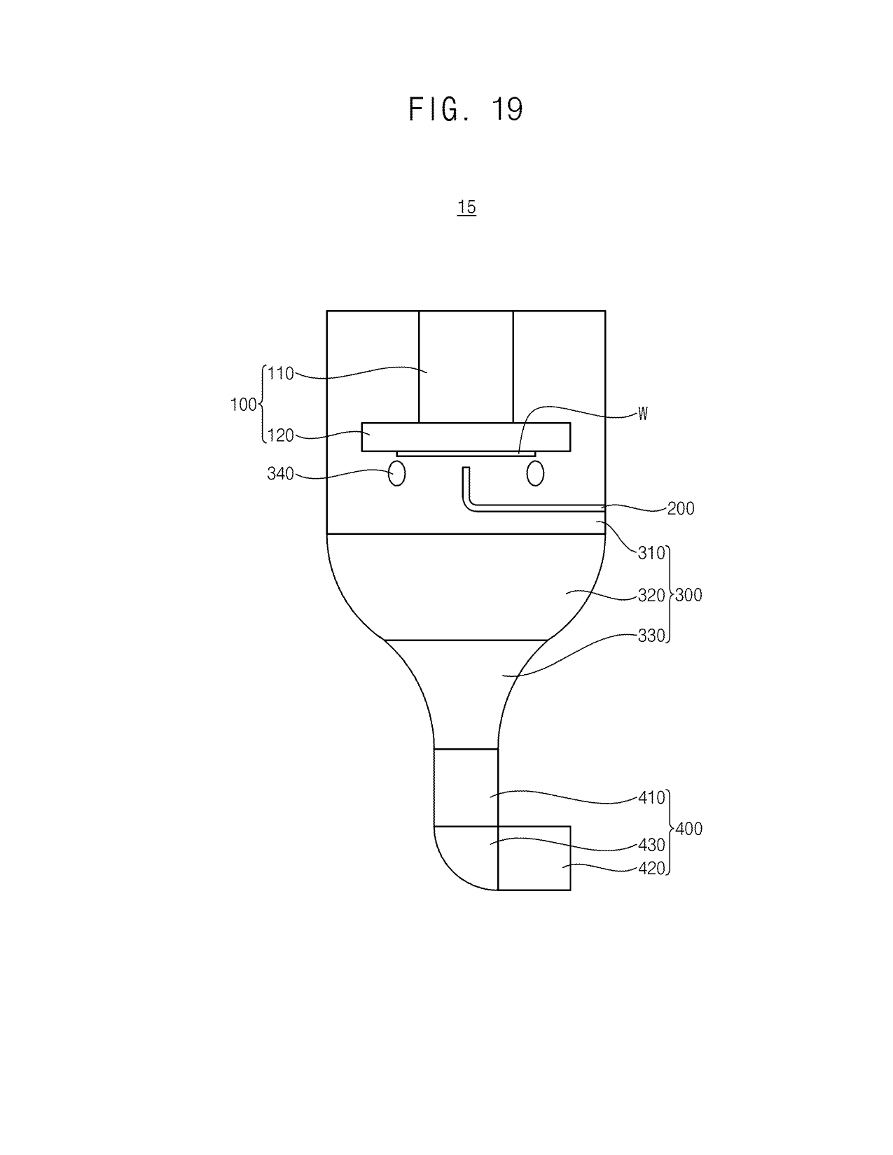

FIG. 19 illustrates a cross-sectional view of an exemplary substrate processing apparatus, consistent with some embodiments of the present disclosure.

The substrate processing apparatus 15 may include substantially the same components as those of the substrate processing apparatus described with reference to FIG. 1, except that a rotational airflow prevention portion 500 is omitted. Accordingly, the same components are denoted by the same reference numerals, and repeated descriptions of the same components may be omitted.

Referring to FIG. 19, a cleaning fluid F sprayed onto a substrate W from a nozzle portion 200 may be primarily exhausted through exhaust holes 340 and secondarily exhausted through an exhaust duct 400. Accordingly, the substrate processing apparatus 15 may function to prevent a phenomenon in which foreign substances are re-dispersed onto the substrate during the cleaning process.

Although exemplary embodiments have been described, the present disclosure should not be limited to these embodiments. It will be understood by one of ordinary skill in the art that variations in form and detail may be made therein without departing from the spirit and scope of the attached claims. It will also be understood by one of ordinary skill in the art that one or more features of one embodiments of this disclosure may be variously combined with one or more features of another embodiment of this disclosure.

What is claimed is:

1. A substrate processing apparatus, comprising:
a substrate support comprising a substrate stage, the substrate stage including a seating surface configured to receive a substrate, the substrate stage being arranged such that the substrate placed on the seating surface faces downward;
a nozzle portion located below the substrate stage and configured to spray a cleaning fluid toward the substrate;
a chamber including a body portion and a curved portion connected to the body portion, the body portion having a cylindrical shape extending vertically downward to surround the substrate stage and the curved portion having a diameter that decreases as the curved portion extends vertically downward; and
an exhaust duct connected to the curved portion of the chamber, wherein the curved portion comprises:
a first curved portion extending vertically downward and having a convex curved surface facing outward and
a second curved portion connected to the first curved portion and extending vertically downward and having a convex curved surface facing inward.

2. The substrate processing apparatus of claim 1, wherein the chamber further comprises at least one exhaust hole disposed on a side surface of the body portion.

3. The substrate processing apparatus of claim 2, wherein the at least one exhaust hole includes a plurality of exhaust holes arranged to surround the substrate stage on the side surface of the body portion, the plurality of exhaust holes being spaced apart from each other.

4. The substrate processing apparatus of claim 2, wherein the at least one exhaust hole is arranged between the substrate stage and the nozzle portion on the side surface of the body portion.

5. The substrate processing apparatus of claim 1, wherein at least a portion of the first curved portion has a first radius of curvature from a first center point, at least a portion of the second curved portion has a second radius of curvature from a second center point, the first curved portion and the second curved portion are connected to each other so as to have a common tangent at a point where a lower surface of the first curved portion and an upper surface of the second curved portion meet.

6. The substrate processing apparatus of claim 5, wherein the second radius of curvature is equal to the first radius of curvature.

7. The substrate processing apparatus of claim 5, wherein the first radius of curvature is within a range of 0.2 times to 0.9 times a diameter of the substrate stage.

8. The substrate processing apparatus of claim 7, wherein the body portion extends to have a first height within a range of 1.2 times to 2.3 times the diameter of the substrate stage.

9. The substrate processing apparatus of claim 1, further comprising a rotational airflow prevention portion that extends vertically downward within an internal space enclosed by the first curved portion and the second curved portion, the rotational airflow prevention portion configured to partition the internal space.

10. The substrate processing apparatus of claim 9, wherein the rotational airflow prevention portion comprises:
a center rod extending vertically downward within the internal space; and
a plurality of plates extending radially from the center rod.

11. The substrate processing apparatus of claim 10, wherein each of the plurality of plates has a planar shape extending vertically downward along a side surface of the center rod.

12. The substrate processing apparatus of claim 10, wherein each of the plurality of plates has a spiral shape extending along a side surface of the center rod and having a center angle between the plurality of plates.

13. The substrate processing apparatus of claim 10, wherein each of the plurality of plates has an outer surface that extends along a profile of an inner circumferential surface of the first curved portion and an inner circumferential surface of the second curved portion.

14. A substrate processing apparatus, comprising:
a substrate support comprising a substrate stage, the substrate stage including a seating surface configured to receive a substrate, the substrate stage being arranged such that the substrate placed on the seating surface faces downward;
a nozzle portion located below the substrate stage and configured to spray a cleaning fluid toward the substrate;
a chamber, including:
a body portion surrounding the substrate support,
a first curved portion connected to the body portion and extending vertically downward to have a convex curved surface facing outward, and
a second curved portion connected to the first curved portion and extending vertically downward to have a convex curved surface facing inward;
at least one exhaust hole disposed on a side surface of the body portion;
an exhaust duct connected to the chamber; and
a rotational airflow prevention portion extending vertically downward within an internal space enclosed by the first curved portion and the second curved portion, the rotational airflow prevention portion configured to partition the internal space.

15. The substrate processing apparatus of claim 14, wherein the at least one exhaust hole is arranged between the substrate stage and the nozzle portion on a side surface of the body portion, and wherein the at least one exhaust hole includes a plurality of exhaust holes arranged to surround the substrate support on the side surface of the body portion, the plurality of exhaust holes being spaced apart from each other.

16. The substrate processing apparatus of claim 14, wherein at least a portion of the first curved portion has a first radius of curvature from a first center point, at least a portion of the second curved portion has a second radius of curvature from a second center point, and the first curved portion and the second curved portion are connected to each other to share a common tangent at a point where a lower surface of the first curved portion and an upper surface of the second curved portion meet.

17. The substrate processing apparatus of claim 16, wherein the first radius of curvature is within a range of 0.2 times to 0.9 times a diameter of the substrate stage, and the second radius of curvature is equal to the first radius of curvature.

18. The substrate processing apparatus of claim 14, wherein the rotational airflow prevention portion comprises:
a center rod extending vertically downward within the internal space; and
a plurality of plates extending radially from the center rod and extending along a profile of an inner circumferential surface of the first curved portion and an inner circumferential surface of the second curved portion.

19. The substrate processing apparatus of claim 17, wherein the body portion extends to have a first height within a range of 1.2 times to 2.3 times the diameter of the substrate stage.

20. A substrate processing apparatus, comprising:
a substrate support comprising a substrate stage, the substrate stage including a seating surface configured to receive a substrate, the substrate stage being arranged such that the substrate placed on the seating surface faces downward;
a nozzle portion located below the substrate stage and configured to spray a cleaning fluid toward the substrate;
a cylindrical body portion extending vertically downward to surround the substrate stage, the cylindrical body portion extending to have a first height within a range of 1.2 times to 2.3 times a diameter of the substrate stage;
a first curved portion connected to the cylindrical body portion and extending vertically downward to have a convex curved surface facing outward, at least a portion of the first curved portion having a first radius of curvature from a first center point;
a second curved portion connected to the first curved portion to share a common tangent at a point where a lower surface of the first curved portion and an upper surface of the second curved portion meets, the second curved portion extending vertically downward to have a convex curved surface facing inward, at least a portion of the second curved portion having a second radius of curvature from a second center point;
a plurality of exhaust holes arranged between the substrate stage and the nozzle portion on a side surface of the cylindrical body portion, the plurality of exhaust holes being arranged to surround the substrate support on the side surface of the cylindrical body portion, the plurality of exhaust holes being spaced apart from each other;
an exhaust duct connected to the second curved portion; and
a rotational airflow prevention portion having a center rod extending vertically downward within an internal space enclosed by the first curved portion and the second curved portion, and a plurality of plates extending radially from the center rod and configured to divide the internal space, an outer surface of each of the plurality of plates extending along a profile of an inner circumferential surface of the first curved portion and an inner circumferential surface of the second curved portion.
